(19) United States
(12) Patent Application Publication
(10) Pub. No.: US 2009/0307414 A1
(43) Pub. Date: Dec. 10, 2009

(54) MEMORY SYSTEM, MEMORY SYSTEM CONTROL METHOD, AND DRIVE RECORDER APPARATUS

(75) Inventors: Hiroshi SUKEGAWA, Tokyo (JP); Takashi SUZUKI, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/391,583

(22) Filed: Feb. 24, 2009

(30) Foreign Application Priority Data
Jun. 4, 2008 (JP) 2008-147192

(51) Int. Cl. G06F 12/16; G06F 11/10; G11C 16/04; G11C 11/34

(52) U.S. Cl. 711/103; 711/162; 714/763; 365/185.17; 365/185.24; 714/E11.034

(57) ABSTRACT

A memory system includes a NAND-type flash memory which includes a plurality of memory cells and can store one-bit, two-bit or more data in one memory cell, and a duplicating-converting circuit configured to duplicate input data by assigning the input data to a predetermined threshold level and another threshold level different from the predetermined threshold level. Moreover, the memory system includes a controller configured to control to store the data duplicated by the duplicating-converting circuit, in the NAND-type flash memory.

### CROSS-REFERENCE TO RELATED APPLICATION

This application is based upon and claims the benefit of priority from the prior Japanese Patent Application No. 2008-147192 filed in Japan on Jun. 4, 2008; the entire contents of which are incorporated herein by reference.

### BACKGROUND OF THE INVENTION

1. Field of the Invention

The present invention relates to a memory system, a memory system control method, and a drive recorder apparatus, and for example, relates to a memory system, a memory system control method, and a drive recorder apparatus including a non-volatile memory.

2. Description of the Related Art

Conventionally, as a storage memory configured to store a large amount of user data, a NAND-type flash memory which is one of non-volatile memories has been used. The NAND-type flash memory, in which the data can be electrically rewritten, has been used, for example, for video storage by a drive recorder apparatus, image storage by a digital camera, and the like.

Many memory systems including such a NAND-type flash memory have been proposed. For example, Japanese Patent Application Laid-Open Publication No. 2006-510155 discloses a technique of recovering data from an unreadable non-volatile memory cell, and improving reliability and a lifetime of the memory cell.

### BRIEF SUMMARY OF THE INVENTION

According to one aspect of the present invention, there can be provided a memory system including: a non-volatile memory including a plurality of memory cells which are controlled to be at any one of 2^{m} (m is a positive integer) kinds of threshold levels and thereby can retain m-bit data; a duplicating-converting section configured to duplicate input data so that m-bit data to be retained in one of the memory cells are assigned to two threshold levels different from each other; and a controller configured to write respective pieces of the input data duplicated by the duplicating-converting section, to memory areas different from each other in the non-volatile memory.

### BRIEF DESCRIPTION OF THE DRAWINGS

FIG. 1 is a block diagram showing a configuration of a drive recorder apparatus including a memory system according to a first embodiment;

FIG. 2 is an explanatory diagram for explaining an example of logical-physical conversion processing in a controller;

FIG. 3 is a diagram showing an example of threshold distributions of a memory cell;

FIG. 4 is a block diagram showing the configuration of the drive recorder apparatus including the memory system according to a second embodiment; and

FIG. 5 is a diagram showing an example of the threshold distributions of the memory cell.

### DETAILED DESCRIPTION OF THE EMBODIMENTS OF THE INVENTION

In a memory system including a NAND-type flash memory, depending on storage needs, data which should be certainly stored, and data which only needs to be stored in any manner even if not certainly, may be mixed.

For example, in a drive recorder apparatus installed in a vehicle or the like, data of several seconds before and after a moment of an accident is critical, and the data is required to have been certainly stored. In contrast, storage also in the case where any accident has not occurred, that is, during ordinary driving, can provide useful data because storage of motions other than motions of a driver's own vehicle may be a witness of another vehicle's accident. Consequently, the data during the ordinary driving is also desired to have been stored if possible.

However, if such storage during the ordinary driving is constantly performed, the data is frequently rewritten into a storage element of the NAND-type flash memory. The NAND-type flash memory is known to have lower data retention characteristics of the storage element as the number of times of rewriting the data increases. In other words, if the accident has occurred and the certain storage has been actually attempted, the storage element may have been already worn out, and the certain storage of the data may not be possible.

In such a case, as a method configured to certainly store the data, usage of a method configured to duplicate input data and store the duplicated input data in the NAND-type flash memory (store the same pieces of the input data separately in different storage element areas in the NAND-type flash memory) is assumed.

However, when the input data is duplicated in the same storage pattern without respect to wear-out characteristics of the storage element, a problem may occur in which if one piece of the data cannot be read out, the other piece of the data cannot be read out either. In other words, in order to perform the certain data storage, even duplicating and storing the data may not be necessarily effective.

Based on the above described knowledge found out by the inventor of the present application, hereinafter, embodiments of the present invention will be described in detail with reference to the drawings.

### First Embodiment

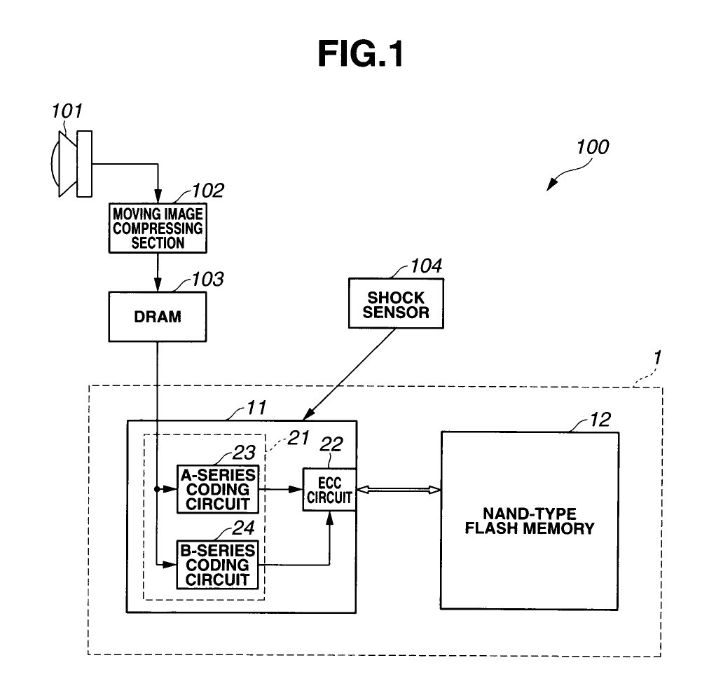

First, based on FIG. 1, a configuration of a drive recorder apparatus including a memory system according to a first embodiment of the present invention will be described. FIG. 1 is a block diagram showing the configuration of the drive recorder apparatus including the memory system according to the first embodiment of the present invention. As shown in FIG. 1, a drive recorder apparatus 100 is configured to include a memory system 1, an image pickup apparatus 101, a moving image compressing section 102, a DRAM 103, and a shock sensor 104.

Moreover, the memory system 1 of the present embodiment is configured to include a controller 11, and a NAND-type flash memory 12 which is a non-volatile memory from which data can be read out and to which the data can be written, under the control of the controller 11.

The NAND-type flash memory 12 of the present embodiment is configured with a plurality of memory cells, and is a four-valued NAND-type flash memory capable of storing two-bit data in one memory cell. Note that the NAND-type flash memory 12 will be described as the four-valued NAND-type flash memory, which, however, may be a NAND-type flash memory capable of storing one-bit, or three or more-bit data in one memory cell. Moreover, a memory cell capable of memorizing one-bit data and a memory cell capable of memorizing two or more-bit data may be mixed within the NAND-type flash memory.

Furthermore, although the present embodiment will be described by using the NAND-type flash memory as the non-volatile memory, the non-volatile memory is not limited to the NAND-type flash memory, and for example, may be a NOR-type flash memory or the like. Besides, each memory cell may include a floating gate structure configured to retain the data by using a change in a threshold voltage of a transistor depending on the number of electrons injected into a floating gate electrode, or may include a MONOS structure configured to retain the data by using the change in the threshold voltage of the transistor depending on the number of electrons or holes trapped by a nitride film interface as a charge accumulation layer.

The controller 11 is configured to include a duplicating-converting circuit 21 and an error correcting code (hereinafter referred to as “ECC”) circuit 22. The controller 11 inputs various control signals (for example, Write Enable/WE, Read Enable/RE, Command Latch Enable CLE, Address Latch Enable ALE, and the like) to the NAND-type flash memory 12, and performs state control of the NAND-type flash memory 12.

Moreover, the controller 11 inputs commands, addresses and the data to the NAND-type flash memory 12 via an input/output terminal (I/O terminal). The controller 11 is assumed to include, for example, a configuration capable of inputting a write command, a read-out command, and an erase command to the NAND-type flash memory 12.

The image pickup apparatus 101 is, for example, a CCD (Charge Coupled Device) camera or the like, which supplies shot image data to the moving image compressing section 102. The image pickup apparatus is not necessarily required to be only one, and for example, two image pickup apparatuses may be installed in order to store frontward and rearward videos from the vehicle. Moreover, three or more image pickup apparatuses may be installed.

The moving image compressing section 102 compresses the image data supplied by the image pickup apparatus 101, according to an arbitrary scheme, and outputs the compressed image data to the DRAM 103.

The DRAM 103 is, for example, a volatile memory including a memory capacity capable of temporarily retaining image data of 20 seconds. The DRAM 103 retains the image data of 20 seconds supplied by the moving image compressing section 102, and sequentially transfers the image data to the controller 11 of the memory system 1. Data transfer control from the DRAM 103 to the controller 11 is performed, for example, by an external system (not shown).

When sensing an impact such as an accident, a quick break operation, or a quick steering wheel operation, the shock sensor 104 outputs a control signal which is a trigger for duplicated storage, to the controller 11 of the memory system 1. In other words, the control signal from the shock sensor is configured not to be inputted to the controller 11 during the ordinary driving.

The controller 11 controls to write, that is, to store the image data transferred from the DRAM 103, into the NAND-type flash memory 12. Particularly, if the control signal has not been inputted from the shock sensor 104, the controller 11 de-duplicates the image data transferred from the DRAM 103, and stores the de-duplicated image data in the NAND-type flash memory 12 (ordinarily writes the image data without duplicating the image data).

Moreover, if the control signal has been inputted from the shock sensor 104, the controller 11 duplicates the image data transferred from the DRAM 103, and stores the duplicated image data in the NAND-type flash memory 12. Since the image data is duplicated and stored in the NAND-type flash memory 12, certainty of the data can be enhanced. The controller 11 duplicates the data storage as described above, by logical-physical conversion processing as described below.

Note that, if the control signal has been inputted from the shock sensor 104, although the controller 11 duplicates and stores the data in the NAND-type flash memory 12, the controller 11 may perform triplication, quadruplication or the like of the data and store the data in the NAND-type flash memory 12. The more a degree of the duplication is increased, the more the certainty of the data to be memorized can be improved.

The duplicating-converting circuit 21 is configured to include an A-series coding circuit 23 and a B-series coding circuit 24. The A-series coding circuit 23 operates either if the control signal is not inputted from the shock sensor 104, or if the control signal is inputted from the shock sensor 104. The A-series coding circuit 23 converts the data transferred from the DRAM 103 into a predetermined code based on a first rule, and outputs the converted data to the ECC circuit 22.

The B-series coding circuit 24 operates only if the control signal is inputted from the shock sensor 104, and is activated if the duplicated storage of the data is performed. Based on the control signal inputted from shock sensor 104, the B-series coding circuit 24 converts the data transferred from the DRAM 103 into a code which is different from the code of the A-series coding circuit 23, based on a second rule, and outputs the converted data to the ECC circuit 22.

Here, “converts into a code which is different” means that the data conversion is performed by the A-series coding circuit 23 and the B-series coding circuit 24 so that, when the input data transferred from the DRAM 103 is assigned to four kinds of data states (four threshold levels described below) which can be taken by each memory cell of the NAND-type flash memory 12, pieces of two-bit input data which make a multi-value compressed pair are assigned to threshold levels different from each other.

If the control signal has not been inputted to the controller 11, the ECC circuit 22 generates an ECC code based on the data inputted from the A-series coding circuit 23, and outputs the data attached with the ECC code to the NAND-type flash memory 12. Moreover, if the control signal has been inputted to the controller 1, the ECC circuit 22 generates the ECC code based on respective pieces of the data inputted from the A-series coding circuit 23 and the B-series coding circuit 24, and outputs the respective pieces of the data attached with the ECC code to the NAND-type flash memory 12.

Furthermore, the ECC circuit 22 applies ECC error correction processing to the data read out from the NAND-type flash memory 12 by the controller 11. If the data coded by the A-series coding circuit 23 is read out, the data applied with the ECC error correction processing is decoded into original information (original input data) based on the first rule. If the data coded by the B-series coding circuit 24 is read out, the data applied with the ECC error correction processing is decoded into the original information (original input data) based on the second rule.

The data which has been completely applied with the error correction and decoded is converted into a video signal, for example, by a video processing section (not shown), and displayed on a displaying section or the like. By checking a video displayed on the displaying section, the accident of another vehicle which has occurred during the ordinary driving can be analyzed, or a situation of the driver's own vehicle or the like at the time of the accident can be judged.

Next, operations of the present embodiment will be described.

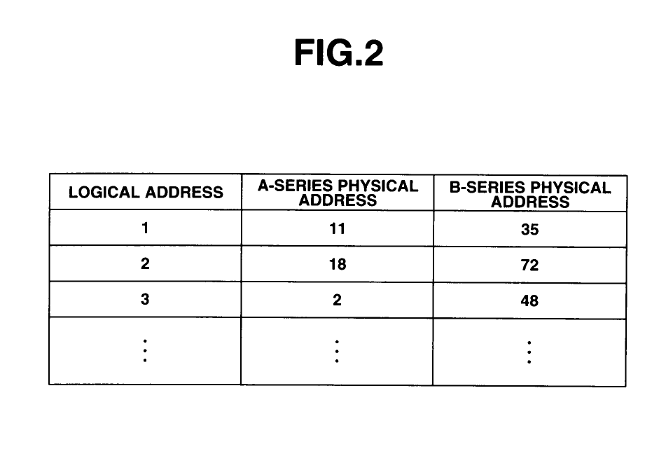

FIG. 2 is an explanatory diagram for explaining an example of the logical-physical conversion processing in the controller 11. As shown in FIG. 2, the controller 11 can convert a logical address of the data transferred from the DRAM 103, into an A-series physical address and a B-series physical address.

When the control signal for the duplicated storage is inputted from the shock sensor 104, the controller 11 stores the duplicated data in the NAND-type flash memory 12, based on the A-series physical address and the B-series physical address.

Specifically, if the control signal for the duplicated storage has not been inputted from the shock sensor 104, the controller 11 performs one-to-one address management between the logical address and the physical address. In other words, the controller 11 causes the A-series physical address to correspond to the logical address of the input data, and moreover, converts the input data in the A-series coding circuit 23.

On the other hand, if the control signal for the duplicated storage has been inputted from the shock sensor 104, the controller 11 performs one-to-two address management between the logical address and the physical address. In other words, the controller 11 causes both the A-series physical address and the B-series physical address to correspond to the input logical address. The controller 11 causes the A-series physical address to correspond to the data converted in the A-series coding circuit 23, and causes the B-series physical address to correspond to the data converted in the B-series coding circuit 24.

As a result, with respect to the data which has been duplicated and stored, if one piece of the data stored in the NAND-type flash memory 12 cannot be read out, that is, if the ECC error correction cannot be applied to the one piece of the data, the controller 11 can read out the other piece of the data. For example, if the data stored in the NAND-type flash memory 12 based on the A-series physical address cannot be read out, the controller 11 reads out the data stored in the NAND-type flash memory 12 based on the B-series physical address.

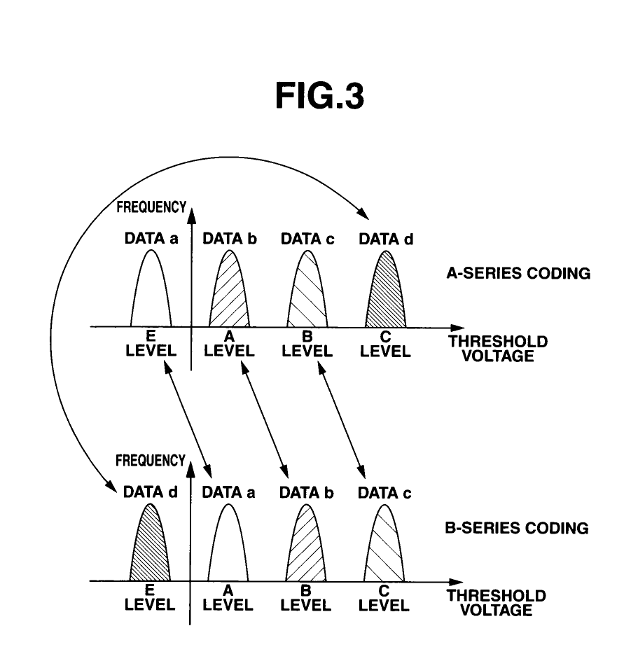

FIG. 3 is a diagram showing an example of threshold distributions of the memory cell. In FIG. 3, a vertical axis indicates frequency, and a horizontal axis indicates the threshold voltage. In the present embodiment, each memory cell can retain two-bit data, and a threshold is controlled to be in any one state of four states (four values) of, from a low voltage side, an E-level (first threshold level), an A-level (second threshold level), a B-level (third threshold level), and a C-level (fourth threshold level).

Moreover, in FIG. 3, an upper threshold distribution indicates a data assignment state in the case of the coding by the A-series coding circuit 23, and a lower threshold distribution indicates the data assignment state in the case of the coding by the B-series coding circuit 24.

Within the NAND-type flash memory 12, predetermined two bits in the input data are selected to be compressed as multi-valued data. Depending on a combination of a data pair to be compressed as the multi-valued data (multi-value compressed pair) (“11”, “01”, “10” and “00”), which threshold level the data is assigned to has been previously defined. Therefore, the controller 11 may define the first rule and the second rule so that respective pieces of the duplicated data are assigned to the threshold levels different from each other within the NAND-type flash memory 12.

In the coding by the A-series coding circuit 23, data a (first data) has been assigned to the E-level, data b (second data) has been assigned to the A-level, data c (third data) has been assigned to the B-level, and data d (fourth data) has been assigned to the C-level. Here, the data a is, for example, “11”, the data b is, for example, “01”, the data c is, for example, “10”, and the data d is, for example, “00”.

In the B-series coding circuit 24, the coding different from the coding by the A-series coding circuit 23 is performed. In the present embodiment, the B-series coding circuit 24 performs coding in which pieces of the data assigned to the respective threshold levels by the A-series coding circuit 23 have been cyclically shifted. In other words, in the coding by the B-series coding circuit 24, the data d has been assigned to the E-level, the data a has been assigned to the A-level, the data b has been assigned to the B-level, and the data c has been assigned to the C-level.

The data inputted to the duplicating-converting circuit 21 is duplicated so that data assignment to each threshold level is performed in a manner being cyclically shifted with respect to each other, in the A-series coding circuit 23 and the B-series coding circuit 24, and each converted data is stored in the NAND-type flash memory 12.

Thereby, the pieces of the duplicated data are caused to correspond to the different threshold levels, respectively. For example, the data a is retained at the E-level and the A-level, the data b is retained at the A-level and the B-level, the data c is retained at the B-level and the C-level, and the data d is retained at the C-level and the E-level.

Note that, as described above, if the one piece of the data which has been duplicated and stored in the NAND-type flash memory 12 cannot be read out, although the other piece of the data is read out, both pieces of the data may be read out and the both read out pieces of the data may be compared with each other. Such comparison between the both pieces of the data enables an error position to be identified. The identification of the error position provides an advantage of an increased number of error-correctable bits.

Moreover, in the case of the duplicated storage due to the accident or the like, there is a conceivable case where the data is desired to be quickly written to the NAND-type flash memory. In such a case, a configuration may be employed in which two NAND-type flash memory chips are included so that the data is simultaneously written to the two chips. In other words, the data coded by the A-series coding circuit 23 is written to one NAND-type flash memory, and in parallel with the writing, the data coded by the B-series coding circuit 24 is written to the other NAND-type flash memory. As a result, the data can be quickly written to the NAND-type flash memory.

As described above, the memory system 1 performs the duplicated storage in which the pieces of the data to be assigned to the same threshold level have been shifted. Therefore, such duplicated storage is effective if a worn-out NAND-type flash memory includes error characteristics which are different between a high voltage application side and a low voltage application side. In other words, in a simple duplicating scheme configured to store the same pieces of the data at the same level in the threshold distribution, if the same threshold level indicates the same error characteristics, an error has been likely to occur in the both pieces of the duplicated data.

In the present embodiment, the duplicating is performed in which the pieces of the data to be assigned to the same level have been shifted. Thereby, the data which should be certainly stored is more likely to have been effectively stored, in comparison with the simple duplicating scheme.

Hence, according to the memory system of the present embodiment, even if the data is stored in the storage element (memory cell) which has been worn out by constantly continuing the data storage, the duplicated storage which invalidates the wear-out characteristics can be performed so as to enhance certainty of the data storage.

Moreover, if the control signal has not been inputted from the shock sensor 104, the controller 11 may not store the image data transferred from the DRAM 103, and may duplicate the image data transferred from the DRAM 103 and store the duplicated image data in the NAND-type flash memory 12 only if the control signal has been inputted. Also in such a case, the data which should be certainly stored is more likely to have been effectively stored, in comparison with the simple duplicating scheme.

Furthermore, whether or not the control signal has been inputted from the shock sensor 104, the controller 11 may always duplicate the image data transferred from the DRAM 103 and store the duplicated image data in the NAND-type flash memory 12. Also in such a case, the data which should be certainly stored is more likely to have been effectively stored, in comparison with the simple duplicating scheme.

Moreover, in the memory system according to the present embodiment, although the number of bits which can be retained by an individual memory cell has been described as two bits, the number is not limited thereto. In other words, the individual memory cell can be configured to be able to retain m (m is a positive integer)-bit data. The duplicating may be performed so that different pieces of data are assigned to respective 2^{m} kinds of data states, or at least one set of data states.

### Second Embodiment

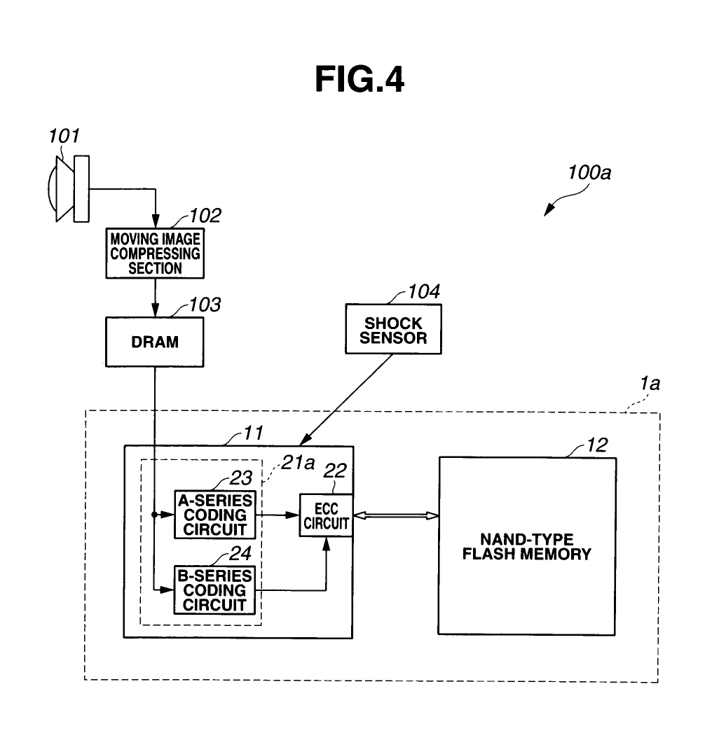

Next, a second embodiment of the present invention will be described. FIG. 4 is a block diagram showing the configuration of the drive recorder apparatus including the memory system according to the second embodiment of the present invention. As shown in FIG. 4, a drive recorder apparatus 100a is configured by using a memory system 1a instead of the memory system 1 of FIG. 1. Moreover, the memory system 1a of the present embodiment is configured by using a duplicating-converting circuit 21a instead of the duplicating-converting circuit 21 of FIG. 1.

The duplicating-converting circuit 21a interchanges the pieces of the data to be assigned to the respective threshold levels with each other between the high voltage application side and the low voltage application side, and performs the duplicated storage in the NAND-type flash memory 12. Other configurations are similar to the configurations of the first embodiment, the description of which is therefore omitted.

Next, operations of the present embodiment will be described.

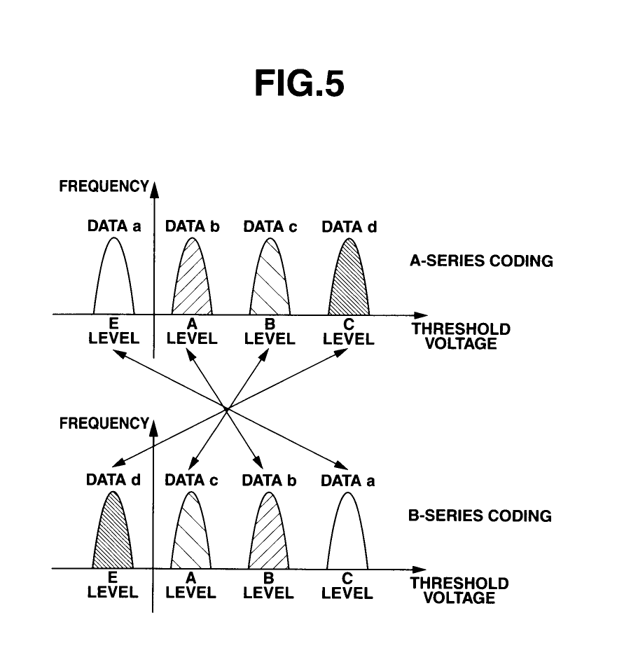

FIG. 5 is a diagram showing an example of the threshold distributions of the memory cell. In FIG. 5, a description of the same operation as the operation of the FIG. 3 is omitted.

In the B-series coding circuit 24, the coding different from the coding by the A-series coding circuit 23 is performed. In the present embodiment, the B-series coding circuit 24 performs coding in which the pieces of the data to be assigned to the respective threshold levels have been interchanged with each other between the high voltage application side and the low voltage application side. In other words, in the coding by the B-series coding circuit 24, the data d has been assigned to the E-level, the data c has been assigned to the A-level, the data b has been assigned to the B-level, and the data a has been assigned to the C-level.

The data inputted to the duplicating-converting circuit 21a is duplicated so that the pieces of the data to be assigned to the respective threshold levels are interchanged with each other between the high voltage application side and the low voltage application side, in the A-series coding circuit 23 and the B-series coding circuit 24, and is stored in the NAND-type flash memory 12.

Thereby, the pieces of the duplicated data are caused to correspond to the threshold levels different from each other. In other words, the data a is retained at the E-level and the C-level, the data b is retained at the A-level and the B-level, the data c is retained at the B-level and the A-level, and the data d is retained at the C-level and the E-level.

As described above, the memory system 1a performs the duplicated storage in which the pieces of the data to be assigned to the respective threshold levels have been interchanged with each other between the high voltage application side and the low voltage application side. Therefore, such duplicated storage is effective if error characteristics of a worn-out flash memory device show the same tendency in a high voltage application state and a low voltage application state.

In the present embodiment, the duplicating is performed in which the threshold levels to be assigned to the same pieces of the data (the same multi-value compressed pair) have been interchanged with each other between the high voltage application side and the low voltage application side. Thereby, the data which should be certainly stored is more likely to have been effectively stored, in comparison with the simple duplicating scheme.

Hence, in the memory system of the present embodiment, similarly to the first embodiment, even if the data is stored in the worn-out storage element, the duplicated storage which invalidates the wear-out characteristics can be performed so as to enhance the certainty of the data storage.

Note that, as different kinds of coding, although the case where the same pieces of the data have been shifted has been described in the first embodiment, and the case where the same pieces of the data have been interchanged with each other between the high voltage application side and the low voltage application side has been described in the second embodiment, methods configured to assign the pieces of the data to the respective threshold levels are not limited to the two cases.

For example, in a memory cell of a floating gate type, an electric charge which has been charged in a high voltage side is easily drawn out. In other words, data which has been stored in the high voltage side is likely to cause an error. Consequently, at least the data stored at the C-level may be stored at another threshold level and duplicated. As a result, a situation can be prevented in which the both pieces of the duplicated data cause errors and the data cannot be read out.

As described above, if the memory systems described in the first and second embodiments are applied to the drive recorder apparatus, the drive recorder apparatus can perform the certain storage even in the case where the accident has occurred.

Moreover, with respect to the memory system according to the present embodiment, the case where two coding circuits of the A-series coding circuit 23 and the B-series coding circuit 24 are included has been described. However, the number of the coding circuits is not limited thereto.

For example, the controller 11 may be configured to include only one coding circuit. In such a case, if the control signal is not inputted from the shock sensor 104, the coding is not particularly performed, and the data inputted to the controller 11 is directly written to the NAND-type flash memory 12. If the control signal is inputted from the shock sensor 104, the data may be duplicated through a route configured to write the data inputted to the controller 11, directly to the NAND-type flash memory 12, and a route configured to write the data converted by the coding circuit.

Moreover, for example, the controller 11 may be configured to include three coding circuits. In such a case, the coding method of the first embodiment and the coding method of the second embodiment may be combined to perform triplicated data storage with data assignment methods different with one another.

The present invention is not limited to the above described embodiments, and various modifications, alterations and the like can be made in a range not changing the gist of the present invention.

What is claimed is:

1. A memory system comprising:
a non-volatile memory including a plurality of memory cells which are controlled to be at any one of 2^{m} (m is a positive integer) kinds of threshold levels and thereby can retain m-bit data;
a duplicating-converting section configured to duplicate input data so that m-bit data to be retained in one of the memory cells are assigned to two threshold levels different from each other; and
a controller configured to write respective pieces of the input data duplicated by the duplicating-converting section, to memory areas different from each other in the non-volatile memory.

2. The memory system according to claim 1, wherein:
the duplicating-converting section codes the input data so that the m-bit data to be retained in one of the memory cells are assigned to two different threshold levels which have been cyclically shifted with respect to each other.

3. The memory system according to claim 2, wherein:
the memory cells are controlled to be at any one of a first threshold level, a second threshold level, a third threshold level, and a fourth threshold level in an order corresponding to a threshold voltage, and the controller can cause any one of first data, second data, third data and fourth data to correspond to each of the threshold levels; and
the duplicating-converting section includes a first series coding circuit configured to convert the input data so that the first data is assigned to the first threshold level, the second data is assigned to the second threshold level, the third data is assigned to the third threshold level, and the fourth data is assigned to the fourth threshold level, and a second series coding circuit configured to convert the input data so that the first data is assigned to the second threshold level, the second data is assigned to the third threshold level, the third data is assigned to the fourth threshold level, and the fourth data is assigned to the first threshold level.

4. The memory system according to claim 3, wherein:
the first series coding circuit converts the input data whether or not a control signal which is a trigger for duplicated storage is inputted; and
the second series coding circuit converts the input data only if the control signal is inputted.

5. The memory system according to claim 1, wherein:
the duplicating-converting section codes the input data so that the m-bit data to be retained in one of the memory cells are assigned to two different threshold levels which have been interchanged with each other between a high voltage application side and a low voltage application side.

6. The memory system according to claim 5, wherein:
the memory cells are controlled to be in four kinds of data states consisting of a first threshold level, a second threshold level, a third threshold level, and a fourth threshold level in an order corresponding to a threshold voltage, and the controller can cause any one of first data, second data, third data and fourth data to correspond to each of the threshold levels; and
the duplicating-converting section includes a first series coding circuit configured to convert the input data so that the first data is assigned to the first threshold level, the second data is assigned to the second threshold level, the third data is assigned to the third threshold level, and the fourth data is assigned to the fourth threshold level, and a second series coding circuit configured to convert the input data so that the first data is assigned to the fourth threshold level, the second data is assigned to the third threshold level, the third data is assigned to the second threshold level, and the fourth data is assigned to the first threshold level.

7. The memory system according to claim 6, wherein:
the first series coding circuit converts the input data whether or not a control signal which is a trigger for duplicated storage is inputted; and
the second series coding circuit converts the input data only if the control signal is inputted.

8. The memory system according to claim 1, further comprising:
an error correcting code circuit configured to attach an error correcting code to the respective pieces of the input data duplicated by the duplicating-converting section,
wherein the controller writes the respective pieces of the input data attached with the error correcting code, to the memory areas different from each other in the non-volatile memory.

9. The memory system according to claim 1, wherein:
the memory cells include a floating gate structure configured to retain the m-bit data by using a change in a threshold voltage of a transistor depending on the number of electrons injected into a floating gate electrode.

10. The memory system according to claim 1, wherein:
the memory cells include a MONOS structure configured to retain the m-bit data by using a change in a threshold voltage of a transistor depending on the number of electrons or holes trapped by a nitride film interface as a charge accumulation layer.

11. The memory system according to claim 1, wherein:
the non-volatile memory is a NAND-type flash memory or a NOR-type flash memory.

12. A memory system control method including a non-volatile memory including a plurality of memory cells which are controlled to be at any one of 2^{m} (m is a positive integer) kinds of threshold levels and thereby can retain m-bit data; the memory system control method comprising:
duplicating input data so that m-bit data to be retained in one of the memory cells are assigned to two threshold levels different from each other; and
writing respective pieces of the duplicated input data to memory areas different from each other in the non-volatile memory.

13. The memory system control method according to claim 12, wherein:
the input data is coded so that the m-bit data to be retained in the one of the memory cells are assigned to two different threshold levels which have been cyclically shifted with respect to each other.

14. The memory system control method according to claim 13, wherein:
the memory cells are controlled to be at any one of a first threshold level, a second threshold level, a third threshold level, and a fourth threshold level in an order corresponding to a threshold voltage, and any one of first data, second data, third data and fourth data can be caused to correspond to each of the threshold levels;
first conversion of the input data is performed so that the first data is assigned to the first threshold level, the second data is assigned to the second threshold level, the third data is assigned to the third threshold level, and the fourth data is assigned to the fourth threshold level; and
second conversion of the input data is performed so that the first data is assigned to the second threshold level, the second data is assigned to the third threshold level, the third data is assigned to the fourth threshold level, and the fourth data is assigned to the first threshold level.

15. The memory system control method according to claim 14, wherein:
the first conversion of the input data is performed whether or not a control signal which is a trigger for duplicated storage is inputted; and
the second conversion of the input data is performed only if the control signal is inputted.

16. The memory system control method according to claim 12, wherein:
the input data is coded so that the m-bit data to be retained in the one of the memory cells are assigned to two different threshold levels which have been interchanged with each other between a high voltage application side and a low voltage application side.

17. The memory system control method according to claim 16, wherein:
the memory cells are controlled to be in four kinds of data states consisting of a first threshold level, a second threshold level, a third threshold level, and a fourth threshold level in an order corresponding to a threshold voltage, and any one of first data, second data, third data and fourth data can be caused to correspond to each of the threshold levels;
first conversion of the input data is performed so that the first data is assigned to the first threshold level, the second data is assigned to the second threshold level, the third data is assigned to the third threshold level, and the fourth data is assigned to the fourth threshold level; and
second conversion of the input data is performed so that the first data is assigned to the fourth threshold level, the second data is assigned to the third threshold level, the third data is assigned to the second threshold level, and the fourth data is assigned to the first threshold level.

18. The memory system control method according to claim 17, wherein:
the first conversion of the input data is performed whether or not a control signal which is a trigger for duplicated storage is inputted; and
the second conversion of the input data is performed only if the control signal is inputted.

19. The memory system control method according to claim 12, further comprising:
attaching an error correcting code to the respective pieces of the duplicated input data; and
writing the respective pieces of the input data attached with the error correcting code, to the memory areas different from each other in the non-volatile memory.

20. A drive recorder apparatus, comprising:
a moving image compressing section configured to compress input data from an image pickup apparatus, according to a predetermined scheme;
a volatile memory including a memory capacity capable of retaining the input data compressed by the moving image compressing section;
a shock sensor configured to output a control signal which is a trigger for duplicated storage when sensing an impact;
a non-volatile memory including a plurality of memory cells which are controlled to be at any one of 2^{m} (m is a positive integer) kinds of threshold levels and thereby can retain m-bit data;
a duplicating-converting section configured to duplicate the input data retained in the volatile memory so that m-bit data to be retained in one of the memory cells are assigned to two threshold levels different from each other; and
a controller configured to, when the control signal is outputted from the shock sensor, write respective pieces of the input data duplicated by the duplicating-converting section, to memory areas different from each other in the non-volatile memory.
